(19) United States
(12) Patent Application Publication
(10) Pub. No.: US 2008/0237839 A1
(43) Pub. Date: Oct. 2, 2008

(54) Semiconductor apparatus and method of manufacturing same

(75) Inventor: Yoshihiko Ino, Miyazaki (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 12/076,220

(22) Filed: Mar. 14, 2008

(30) Foreign Application Priority Data
Mar. 29, 2007 (JP) 2007-088547

(51) Int. Cl. H01L 23/053

(52) U.S. Cl. 257/704; 257/E23.188

(57) ABSTRACT

A semiconductor apparatus and a method of manufacturing same can simplify the manufacturing process and prevent a decrease in production yield without decreasing in sensor sensitivity. A semiconductor apparatus includes a package having a first region having a first thickness, a second region having a second thickness greater than the first thickness, the second region being surrounded by the first region, a third region having a third thickness greater than the second thickness, the third region being surrounded by the second region, and at least one connection pad electrically provided in the third region and connected to an external of the package; a sensor chip having a first weight section, a fixed section surrounding the first weight section and being separated from the first weight section, and a beam section having an elasticity and connecting the first weight section to the fixed section, the fixed section being positioned at the second region of the package; and a second weight section separated from the fixed section and the beam section and connected to the first weight section via an adhesive layer.

### BACKGROUND OF THE INVENTION

1. Field of the Invention

The present invention relates to a semiconductor apparatus and a method of manufacturing same, and more particularly, to a semiconductor apparatus and method of manufacturing same, by which respective accelerations in three dimensions can be determined by using a three-dimensional acceleration sensor.

2. Description of the Related Art

In recent years, acceleration sensors have come to be used widely in various industrial fields, such as self-propelling vehicles, robots, and various other high-precision equipment. There has been a sharp increase in demand for semiconductor apparatuses which are installed with semiconductor acceleration sensors based on MEMS (Micro Electro Mechanical System) technology, from the viewpoint of their compact size and light weight, the accurate and reliable operation they provide, and their low cost, among other factors.

There are semiconductor acceleration sensors which determine acceleration by utilizing a piezo resistance effect, in other words, the phenomenon in which the resistance changes in directly proportional to the generated stress. The semiconductor acceleration sensor is generally mounted as a sensor chip inside a ceramic package, thereby forming a semiconductor apparatus.

In general, a conventional three-dimensional acceleration sensor is, for example, constituted by a weight section centrally formed in the semiconductor apparatus, four beam sections having elastic properties, one end of the four beam sections being respectively connected to the weight section, and a frame-shaped fixed section, to which the other ends of the four beam sections are respectively fixed. A piezo resistance element is formed on each of the beam sections, and by connecting the beam sections with wirings, a “Wheatstone bridge” circuit is formed.

A velocity change of the semiconductor apparatus having the sensor chip distorts the beam sections distort due to a stress created by inertia of the weight section. And also, the piezo resistance elements formed in the beam sections bend, thus changing resistance values of the piezo resistance elements because of the bending. The resistance changes of the piezo resistance element causes a change of a resistance balance of the Wheatstone bridge circuit. By measuring the change in the resistance balance as current changes or voltage changes, accelerations can be detected. A conventional sensor chip provided in the conventional acceleration sensor is disclosed in, for example, Japanese Patent No. 2127840.

However, in a conventional sensor chip, in order to increase a sensor sensitivity, it is necessary to form beam sections to a thinner dimension than a weight section and fixed sections, and thus complicating a manufacturing process. Furthermore, if the beam sections are processed to a thin dimension, there is also a possibility that they may break, thus decreasing a production yield.

### SUMMARY OF THE INVENTION

Therefore, the present invention is devised in view of the aforementioned problems, an object thereof being to provide a semiconductor apparatus and a method of manufacturing same whereby it is possible to simplify the manufacturing process and to prevent a decrease in production yield, without a decrease in sensor sensitivity.

According to a first aspect of the present invention, there is provided a semiconductor apparatus including a package having a first region having a first thickness, a second region having a second thickness greater than the first thickness, the second region being surrounded by the first region, a third region having a third thickness greater than the second thickness, the third region being surrounded by the second region, and at least one connection pad electrically provided in the third region and connected to an external of the package; a sensor chip having a first weight section, a fixed section surrounding the first weight section and being separated from the first weight section, and a beam section having an elasticity and connecting the first weight section to the fixed section, the fixed section being positioned at the second region of the package; and a second weight section separated from both of the fixed section and the beam section and being connected to the first weight section via an adhesive layer.

According to a second aspect of the present invention, there is provided a semiconductor apparatus including: a package having a first region having a first thickness, and a second region having a second thickness greater than said first thickness; the second region being surrounded by the first region; and a connection terminal electrically connected to an external of the package; a sensor chip having a first weight section; a fixed section separated from the first weight section, surrounding the first weight section and having an electrode pad; and a beam section having an elasticity and connecting the first weight section to the fixed section; the connection terminal being connected to the electrode pad and the sensor chip being disposed on the package; and a second weight section separated from the fixed section and the beam section, the second weight section being connected to the first weight section via a connection layer.

According to a third aspect of the present invention, there is provided a semiconductor apparatus comprising: a package having a first region having a first thickness, a second region having a second thickness greater than the first thickness, the second region surrounded by first region, and a connection terminal provided in the first region and connected electrically to an external of the package; a sensor chip, disposed on the package, having a fixed section having an electrode pad, a first weight section surrounding the fixed section while being separated from the fixed section, and a beam section having an elasticity and connecting the fixed section to the first weight section, the connection terminal being connected to the electrode pad; and a second weight section formed on the first weight section and partially covering the fixed section, the second weight being separated from the fixed section.

According to the present invention, it is possible to achieve a semiconductor apparatus and a method of manufacturing same whereby the manufacturing process can be simplified and the decrease in the production yield can be prevented, without decreasing the sensor sensitivity.

### BRIEF DESCRIPTION OF THE DRAWINGS

FIG. 1 is a plan view of a semiconductor apparatus according to a first embodiment of the present invention;

FIG. 2 is a cross-sectional view along A-A′ in FIG. 1;

FIG. 3 is a plan view of a semiconductor apparatus according to a second embodiment of the present invention;

FIG. 4 is a cross-sectional view along A-A′ in FIG. 3;

FIG. 5 is a plan view of a semiconductor apparatus according to a third embodiment of the present invention;

FIG. 6 is a cross-sectional view along A-A′ in FIG. 5;

FIG. 7 is a plan view of a semiconductor apparatus according to a fourth embodiment of the present invention;

FIG. 8 is a cross-sectional view along A-A′ in FIG. 7;

FIGS. 9A to 9D are cross-sectional views of intermediate products for describing a method of manufacturing a sensor chip according to the first embodiment of the present invention;

FIGS. 10A to 10D are cross-sectional views of intermediate products for describing a method of manufacturing a semiconductor apparatus according to the first embodiment of the present invention;

FIGS. 11A to 11D are cross-sectional views of intermediate products for describing a method of manufacturing a sensor chip according to the second embodiment of the present invention;

FIGS. 12A to 12D are cross-sectional views of intermediate products for describing a method of manufacturing a semiconductor apparatus according to the second embodiment of the present invention;

FIGS. 13A to 13D are cross-sectional views of intermediate products for describing a method of manufacturing a semiconductor apparatus according to the third embodiment of the present invention;

FIGS. 14A to 14D are cross-sectional views of intermediate products for describing a method of manufacturing a sensor chip according to the fourth embodiment of the present invention; and

FIGS. 15A to 15D are cross-sectional views of intermediate products for describing a method of manufacturing a semiconductor apparatus according to the fourth embodiment of the present invention.

### DETAILED DESCRIPTION OF THE INVENTION

Below, preferred embodiments for implementing the present invention are described in detail in conjunction with the drawings. In the following description, the views simply depict schematic views of shapes, sizes and positional relationships, in order to gain an understanding of the content of the present invention, and therefore the present invention is not limited to the shapes, sizes and positional relationships illustrated in the drawings. Furthermore, in the views, the composition of portions which cannot actually be seen in practice may be indicated by broken lines, in order to clarify the composition. Moreover, the figures indicated as examples below are no more than preferred examples relating to the present invention, and therefore the present invention is not limited to the figures indicated below.

### First Embodiment

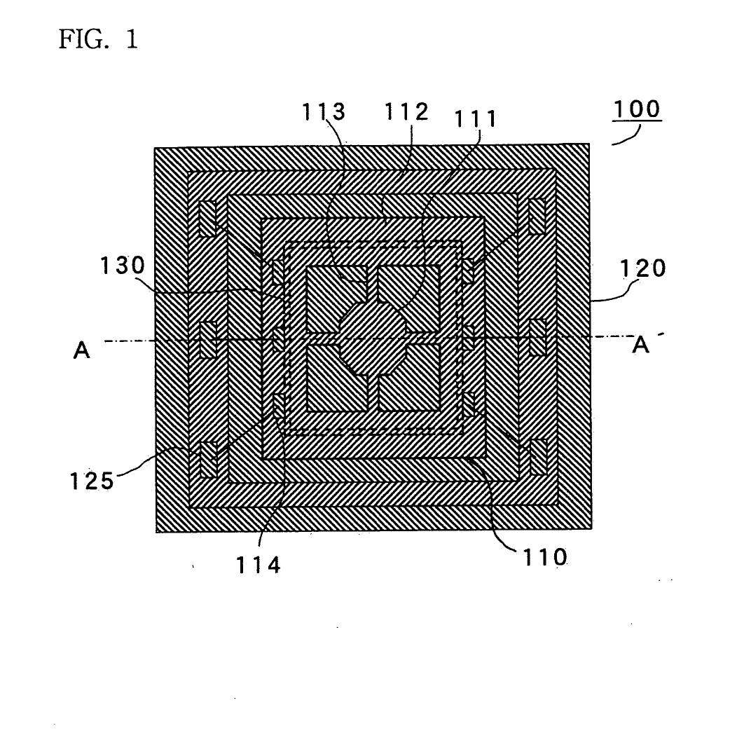

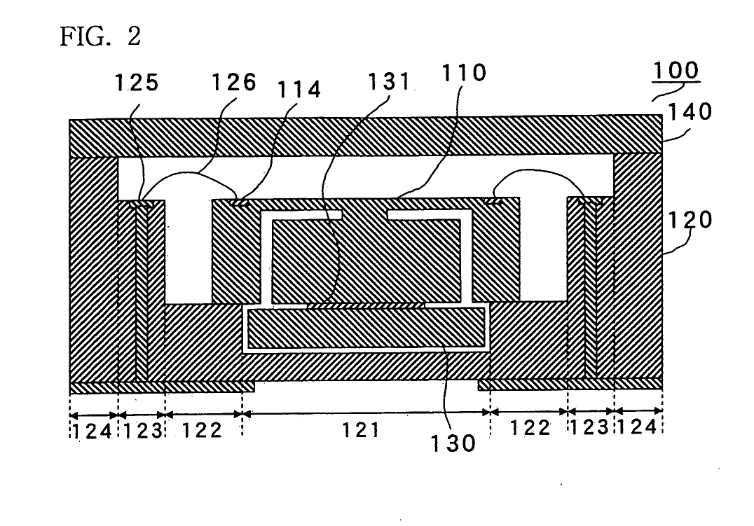

FIG. 1 is a plan view of a semiconductor apparatus according to a first embodiment of the present invention, and in this illustration, the lid section is omitted in order to clarity the positional relationships within the semiconductor apparatus. Furthermore, FIG. 2 is a cross-sectional view along A-A′ of the semiconductor apparatus in FIG. 1. In order to simplify the description, in FIG. 1, the direction away from the viewer of the drawing is taken to be the vertical direction, and the side of the lid section in FIG. 2 is taken to be the upper side in the vertical direction. Furthermore, in FIG. 2, the direction away from the viewer of the drawing is taken to be the horizontal direction.

The semiconductor apparatus 100 comprises a sensor chip 110, a package 120 on which the sensor chip 110 is mounted, an additional weight section 130 connected to the sensor chip 110, and a lid section 140, which covers the sensor chip 110 and is connected to the package 120. In the illustration in FIG. 1, the lid section 140 is omitted, as stated previously, the sensor chip 110 is depicted by thick lines, and the respective outlines of the additional weight section 130 and a first region of the package 110 are depicted by dotted lines.

The sensor chip 110 comprises a weight section 111, a fixed section 112 which surrounds the weight section 111 while being separated from the weight section 111, and beam sections 113 which connect the weight section 111 with the fixed section 112. Furthermore, the sensor chip 110 in the first embodiment of the present invention is formed by using an SOI substrate, constituted by a supporting substrate, an insulating layer formed on the supporting substrate, and an SOI layer formed on the insulating layer, by means of the method of manufacturing the sensor chip 110 which is described below.

The weight section 111, the fixed section 112 and the beam sections 113 are formed integrally in the 111 layer of the sensor chip 110, and are defined as separate regions in accordance with their respective roles. In other words, in the SOI layer of the SOI substrate which forms the sensor chip 110, the region which is fixed to the package 120 irrespective of external stress constitutes the fixed section 112, the portion which is displaced principally due to external stress constitutes the weight section 111, and the regions which bend in accordance with the amount of displacement of the fixed section 112 and the weight section 111 constitute the beam sections 113.

The weight section 111 is constituted by an SOI layer, an insulating layer, and a supporting substrate, and when viewed in the vertical direction, the SOI substrate in the weight section 111 and the insulating layer of the weight section 111 have substantially the same shape and are mutually overlapping. Furthermore, the center of the supporting substrate of the weight section 111 coincides with the center of the SOI layer of the weight section 111, but the supporting substrate has a larger size than the weight section 111.

The beam sections 113 are constituted by an SOI layer, and have a long rectangular shape. The beam sections 113 of the sensor chip 110 in the first embodiment of the present invention are disposed, one respectively on each of the four edges of the fixed section 112, and they support the weight section 111. Furthermore, piezo resistance elements having a resistance which alters in accordance with a bending action are formed on the beam sections 113.

The fixed section 112 is constituted by an SOI layer, an insulating layer and a supporting substrate, and is shaped as a frame having a square outer perimeter and a prescribed width B; when viewed in the vertical direction, the SOI layer, the insulating layer and the supporting substrate have substantially the same shape and are mutually overlapping. Furthermore, electrode pads 114 which are connected to the piezo resistance elements via wires (not illustrated) are formed on top of the fixed section 112. The thickness of the supporting substrate of the fixed section 112 is the same as the thickness of the supporting substrate of the weight section 111.

The package 120 comprises a first region 121 of a first thickness in the central portion of the package 120, a second region 122 of a second thickness greater than the first thickness, which surrounds the first region 121, a third region 123 of a third thickness greater than the second thickness, which surrounds the second region 122, and a fourth region 124 of a fourth thickness greater than the third thickness, which surrounds the third region 123.

The first region 121 is a region which is narrower than the outer perimeter of the sensor chip 110, being disposed at a width of B to the inner side of the outer perimeter of the sensor chip 110, and which is broader than the inner perimeter of the sensor chip 110. Here, the first region 121 should be a region which is larger than the shape of the additional weight section 130, described hereinafter, when viewed in the vertical direction. In this case, for example, desirably, the first region 121 is a region having an outer perimeter which is greater, by a prescribed width, than the outer perimeter of the additional weight section 130. By this means, it is possible to restrict the displacement of the additional weight section 130, when excessive external stress is applied to same, thereby preventing breakage of the sensor chip 110. For example, these beneficial effects can be obtained by forming the first region 121 to be a region which is larger than the external perimeter of the external weight section 130 by a prescribed width of approximately 3 to 5 μm (micrometers).

The second region 122 is the region where the sensor chip 110 is installed and has a width that is sufficient to allow the installation of the sensor chip 110. Furthermore, the second region 122 has a second thickness, which is greater than the first thickness of the first region 121. Here, the second region 122 need not be a region which completely surrounds the outer perimeter of the first region 121. For example, if the sensor chip 110 is installed so as to be supported only at the four corner sections thereof, then it is sufficient to form the second region 122 at the four corner sections of the first region only. Reducing the fixing surface between the sensor chip 110 and the package 120 causes the fixing force to decline, but it also reduces the stress created by difference in the coefficient of linear expansion between the sensor chip 110 and the package 120. By diminishing the application of unwanted stresses to the sensor chip 110, beneficial effects are obtained in that zero-point correction of the sensor chip 110 is facilitated, and consequently, the determination accuracy is improved. In the semiconductor apparatus according to the first embodiment of the present invention, the sensor chip 110 and the package 120 are bonded together by means of a silicone rubber adhesive having an elasticity of 20 MPa or less. Consequently, by fixing the sensor chip 120 by means of an adhesive having a low elasticity, the stress described above is alleviated, in addition to which it is also possible to improve the resistance to impact. Furthermore, the fixed section 112 of the sensor chip 110 is installed in contact with the second region 122, and it is installed in such a manner that a projecting section extending over the first region 121 is formed on the junction surface of the fixed section 112 which is bonded with the second region 122. By means of this projecting section which extends from the junction surface of the fixing section 112 to the first region 121, it is possible to restrict the displacement of the additional weight section 130, which is described hereinafter, in the upward vertical direction.

The third region 123 is a region where connection pads 125 are formed. The connection pads 125 are connected electrically to external electrodes on an outer substrate on which the semiconductor apparatus 100 is mounted, for example, on a mounting substrate. Here, if the package 120 is made of a ceramic material, for example, then the connection pads 125 are formed by bonding together a plurality of layers, and the wires which connect the connection pads 125 with the external electrodes are formed by wires passing between the layers, and wires passing through a plurality of layers (not illustrated). If the package 120 is formed from a silicon wafer, or the like, then the wires which connect the connection pads 125 with the external electrodes are formed by means of through electrodes, or the like (not illustrated). Moreover, the third region 123 has a third thickness which is greater than the second thickness of the second region 122, and the third thickness is set in such a manner that the connection pads 125 and the electrode pads 114 of the sensor chip 110 are positioned at the same height. In this case, it is not necessary for the connection pads 125 and the electrode pads 114 to be at exactly the same height. However, if the connection pads 125 and the electrode pads 114 are at different heights, and if the height differential is notably large, then when the connection pads 125 and the electrode pads 114 are connected by wire bonding, there is a problem in that disconnection of the bonding wires 126 is liable to occur. Therefore, the third thickness is set in such a manner that the connection pads 125 and the electrode pads 114 are positioned at approximately the same height, and the height differential between same is within a range which does not give rise to problems of this kind.

The fourth region 124 is the region forming the outermost perimeter of the package 120, and the lid section 140 which covers the sensor chip 110 while being separated from the chip 110 is installed in this fourth region. The fourth thickness of the fourth region 124 is set in such a manner that it is separated from the sensor chip 110, as well as being separated from the bonding wires 126 which connect the connection pads 125 with the electrode pads 114, for example. The package 120 is constituted by the first region 121, the second region 122, the third region 123 and the fourth region 124.

The additional weight section 130 is connected to the weight section 111 of the sensor chip 110 by means of an adhesive layer 131. The additional weight section 130 is disposed so as to be separated from the package 120, within the first region 121 of the package 120. In this case, the additional weight section 130 is disposed in such a manner that when viewed in the vertical direction, the center thereof coincides with the center of the weight section 111. Furthermore, as described above, the junction surface of the fixed section 112 of the sensor chip 110 has a portion which extends over the first region 121, and the outer circumference of the additional weight section 130 is disposed between the extended section of the junction surface and the first region 121 of the package 120, while being separated respectively from same. In this case, the distance between the extended section of the junction surface and the additional weight section 130 is determined by means of the adhesive layer 131. In other words, the thickness of the adhesive layer 131 forms the distance between the extended section of the junction surface and the additional weight section 130.

The additional weight section 130 is restricted respectively in the horizontal direction by the distance with respect to the first region 121, and in the vertical direction, by the distance with respect to the extended section of the junction surface of the fixed section 121. Furthermore, if an adhesive layer is applied to the whole surface of the fixed section 112 of the sensor chip 110, then the distance between the extended section of the junction surface and the additional weight section 130 will be the difference between the thickness of the adhesive layer 131 and the thickness of the adhesive layer applied to the fixed section 112. The additional weight section 130 is made, for example, of a copper alloy having a specific weight of 8.9 g/cm³. The specific weight of the silicon material used for the sensor chip 110 is approximately 2.3 g/cm³, and therefore the specific weight of the additional weight section 130 is some four times greater. As a result of this, it is possible to increase the overall mass of the weight, without increasing the mass of the weight section of the sensor chip 110, and therefore the sensor chip 110 can be formed to a compact size. The material of the additional weight section 130 may be a material other than copper alloy, such as silicon, or the like. Since it is possible to control the total mass of the weight section 111 and the additional weight section 130 by means of the additional weight section 130, then it is also possible to reduce the size of the weight section 111 of the sensor chip 110. By this means, it becomes possible to make the sensor chip 110 more compact in size, and to improve the sensitivity of the sensor chip 110.

The lid section 140 is positioned at the fourth region 124 of the package 120 in order to seal the sensor chip 110 hermetically. The lid section 140 and the fourth region of the package 120 are bonded together by means of a commonly known adhesive.

A semiconductor apparatus according to the first embodiment of the present invention is formed by means of the composition described above.

According to the first embodiment of the present invention, by providing the additional weight section, the determination sensitivity can be improved, as well as being able to make the sensor chip, and hence the semiconductor apparatus, more compact in size. Furthermore, impact resistance is improved, since the amount of displacement of the additional weight section can be restricted by means of the recess section (first region 121) of the package in which the additional weight section is accommodated, and the fixed section of the sensor chip.

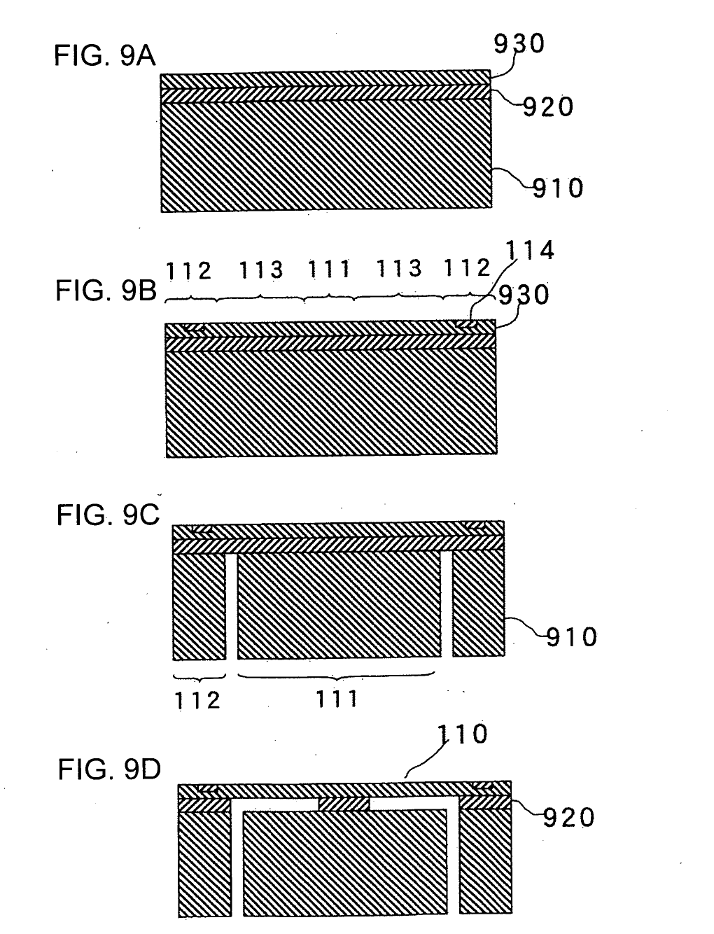

Next, the method of manufacturing a sensor chip 110 according to a first embodiment of the present invention will be described, with reference to FIG. 9A and FIG. 9B. As shown in FIG. 9A, the sensor chip 110 according to the first embodiment of the present invention is formed by a laminated substrate comprising three layers: a supporting substrate 910, an insulating layer 920 and an SOI layer 930. As shown in FIG. 9B, elements which are necessary for the operation of the acceleration sensor, such as electrode pads 114 and piezo resistance elements (not illustrated), wires (not illustrated), and the like, are formed in the SOI layer 930, and through holes for demarcating the weight section 111, the fixed section 112 and the beam sections 113 are formed (not illustrated).

As shown in FIG. 9C, through holes which demarcate the weight section 111 and the fixed section 112 are formed in the supporting substrate 910, from the rear surface side. Thereupon, as shown in FIG. 9D, the sensor chip 110 according to the first embodiment of the present invention is formed by removing a portion of the insulating layer 920.

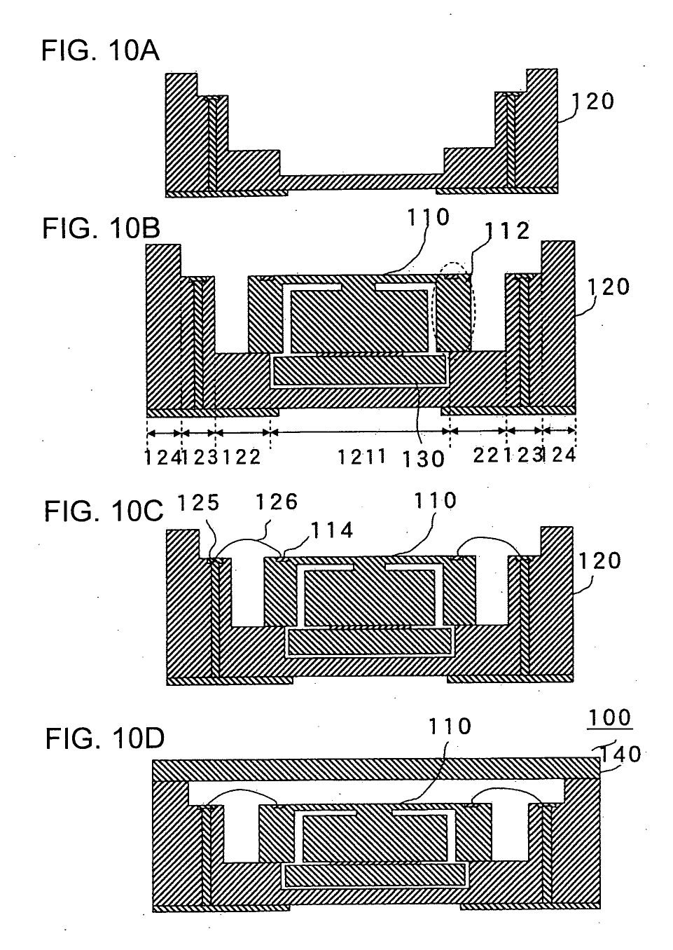

Next, the method of manufacturing a semiconductor apparatus 100 according to the first embodiment of the present invention will be described with reference to FIG. 10A to FIG. 10D. As shown in FIG. 10A, a package 120 is prepared. As shown in FIG. 10B, the fixed section 112 of the sensor chip 110 is mounted on the second region 122 of the package 120. In this case, an additional weight section 130 is connected to the sensor chip 110, and the additional weight section 130 is disposed inside the first region 121 of the package 120, in such a manner that it is separated from the package 120.

As shown in FIG. 10C, the electrode pads 114 of the sensor chip 110 and the connection pads 125 of the package 120 are connected by means of bonding wires 126. As shown in FIG. 10D, a lid section 140 which hermetically seals the interior of the package 120 is formed. By means of the steps described above, the semiconductor apparatus 100 according to the first embodiment is formed.

### Second Embodiment

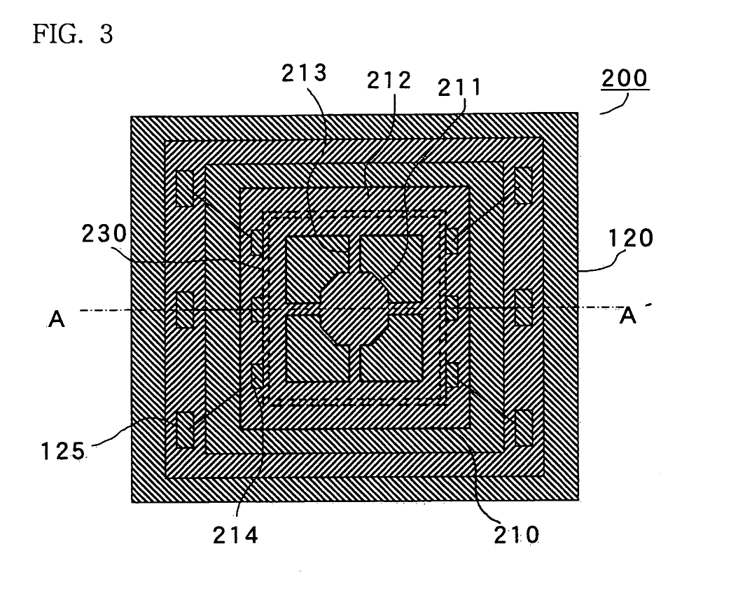

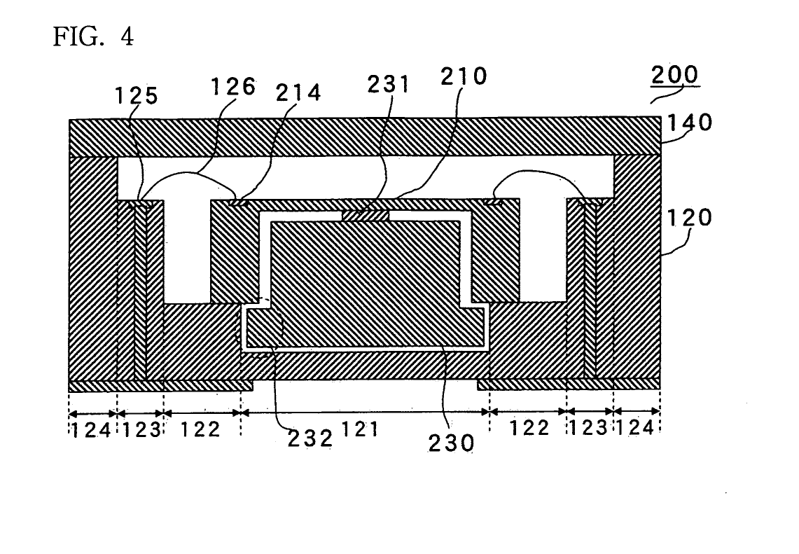

FIG. 3 is a plan view of a semiconductor apparatus according to a second embodiment of the present invention, and the lid section is omitted from this drawing in order to illustrate clearly the positional relationships inside the semiconductor apparatus. Furthermore, FIG. 4 is a cross-sectional view along A-A′ of the semiconductor apparatus in FIG. 3. Parts which are the same as those of the first embodiment are labeled with the same reference numerals and detailed description thereof is omitted here.

When compared with the semiconductor apparatus according to the first embodiment, the semiconductor apparatus 200 according to the second embodiment of the present invention differs in that it comprises a sensor chip 210 and an additional weight section 230 which are of different shape to the sensor chip 110 and the additional weight section 130.

The sensor chip 210 has a similar composition to that of the sensor chip 110 according to the first embodiment of the present invention, apart from the fact that the shape of the weight section 111 is different. More specifically, the sensor chip 210 comprises a weight section 211, a fixed section 212 and beam sections 213; the fixed section 212 has the same composition as the fixed section 112 of the sensor chip 110, and the beam sections 213 have the same composition as the beam sections 113 of the sensor chip 110. The weight section 211 is constituted by the SOI layer in which the beam sections 213 are formed, and it has a different form with respect to the weight section 111 of the sensor chip 110 in that it is not formed on an insulating layer and a supporting substrate. In this way, the form of the weight section 211 in the sensor chip 210 is simplified in comparison with the first embodiment of the present invention, and therefore it is possible to achieve a form which allows simplification of the manufacture of the sensor chip 210, as well as improvement in the production yield.

The package 120 used in the second embodiment of the present invention is similar to that of the first embodiment, and the sensor chip 210 is disposed in a similar manner to the first embodiment.

The additional weight section 230 extends inside the fixed section 212 of the sensor chip 210, and is constituted by a section which connects with the weight section 211 and a section which is disposed inside the first region 121 of the package 120. The additional weight section 230 has a projecting section 232 which is separated respectively from the first region 121, the side faces of the second region 122 and the extended section of the fixed section 212 of the sensor chip 210. By means of this projecting section 232, similarly to the first embodiment, excessive displacement can be restricted in respective directions, namely, displacement in the upward vertical direction is restricted by means of the extended section of the fixed section 212, displacement in the horizontal direction is restricted by means of the side faces of the second region 122, and displacement in the downward vertical direction is restricted by means of the first region 121. It is also possible to restrict displacement in the horizontal direction by means of the side faces of the fixed section 212 of the sensor chip 210, instead of the side faces of the second region 122. Moreover, if the distance between the projecting section 232 and the side face of the second region 122, and the distance between the projecting section 232 and the fixed section 212, are equal, then it is also possible to restrict movement by means of the side faces of both members. Furthermore, in comparison with the first embodiment, the majority of the portion forming the weight is constituted by the additional weight section 230, and there is increased freedom of design in relation to the mass of the weight. This is also an effective means of achieving a more compact design, since, by using metal, or the like, for the additional weight section 230 in order to achieve sufficient mass with a small volume, it is possible to reduce the thickness of the fixed section 212. The adhesive layer 231 can be set and formed in a similar fashion to the first embodiment of the present invention and therefore detailed description thereof is omitted here.

The lid section 140 used in the second embodiment of the present invention is the same as that of the first embodiment, and it is bonded to the package 120 in a similar fashion to the first embodiment.

By means of the composition described above, the semiconductor apparatus according to the second embodiment of the present invention is formed. According to this second embodiment of the present invention, it is possible to achieve impact resistance similar to that of the first embodiment. Moreover, by making the volume of the additional weight section greater than in the first embodiment, increased freedom of design is gained in relation to defining the mass of the weight, and it also becomes possible to achieve an even more compact size. Furthermore, the manufacture of the sensor chip is facilitated and the production yield of the sensor chip is improved, as well as being able to reduce costs accordingly.

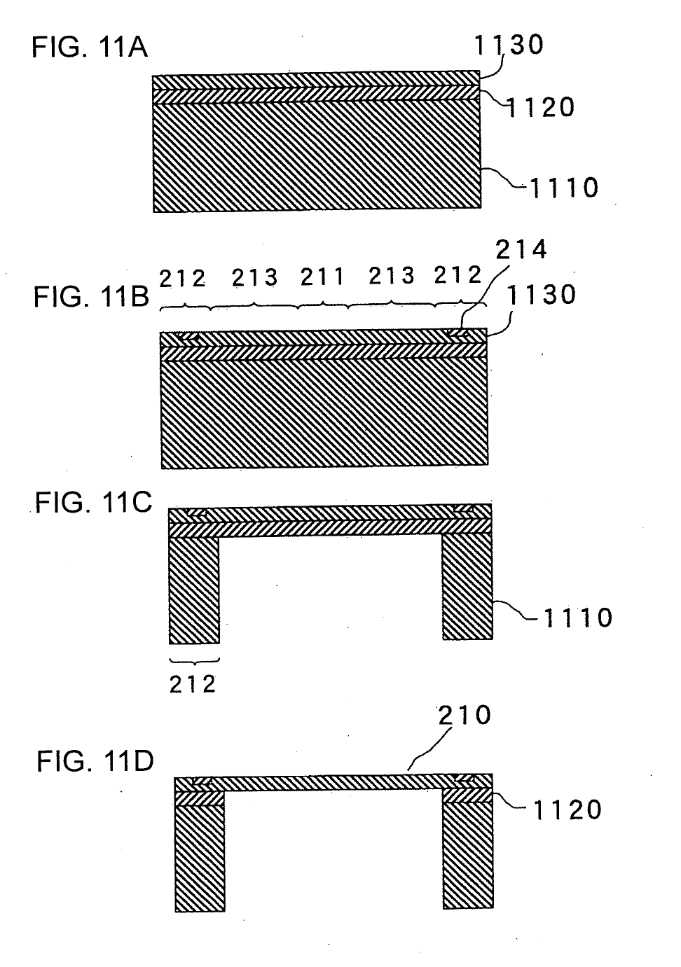

Next, the method of manufacturing the sensor chip 210 according to the second embodiment of the present invention will be described with reference to FIG. 11A to FIG. 11D. As shown in FIG. 11A, the sensor chip 210 according to the second embodiment of the present invention is formed by a laminated substrate comprising three layers, namely, a supporting substrate 1110, an insulating layer 1120, and an SOI layer 1130.

As shown in FIG. 11B, elements required for the operation of the acceleration sensor, such as connection pads 214 and piezo resistance elements (not illustrated), wires (not illustrated), and the like, are formed on the SOI layer 1130, and through holes for demarcating the weight section 211, the fixed section 212 and the beam sections 213 are formed (not illustrated).

As shown in FIG. 11C, a through hole for forming the fixed section 212 is formed in the supporting substrate 1110, from the rear surface side. Thereupon, as shown in FIG. 11D, a portion of the insulating layer 1120 is removed, whereby the sensor chip 210 according to the second embodiment of the present invention is formed.

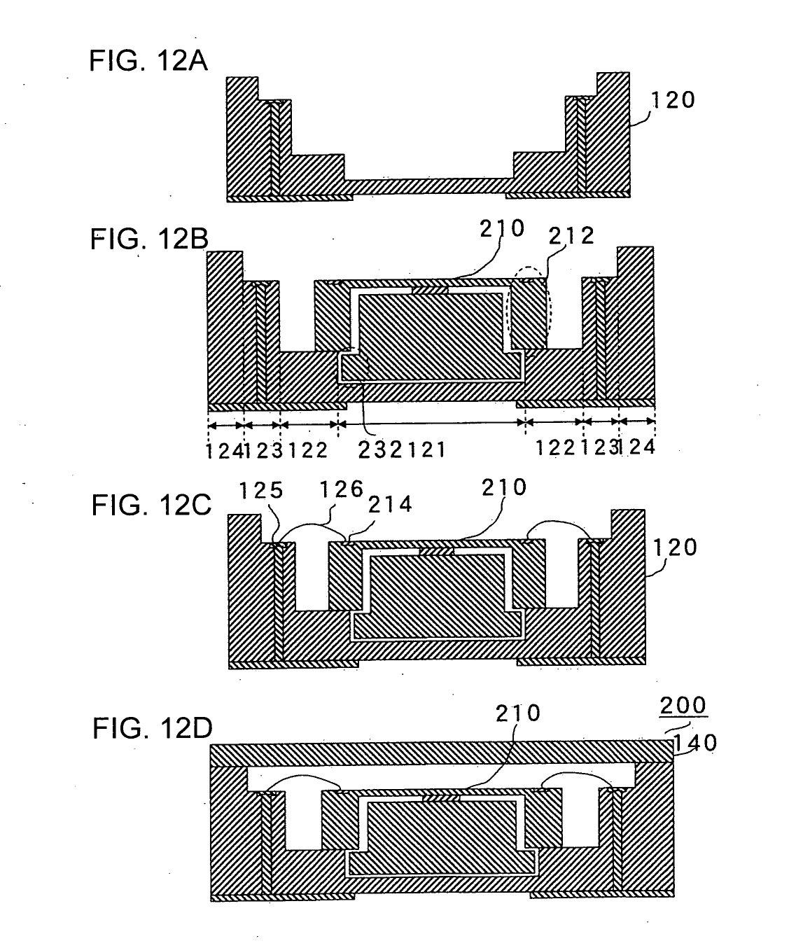

Next, the method of manufacturing the semiconductor apparatus 200 according to the second embodiment of the present invention will be described with reference to FIG. 12A to FIG. 12D. As shown in FIG. 12A, a package 120 is prepared. As shown in FIG. 12B, the fixed section 212 of the sensor chip 210 is installed on the second region 122 of the package 120. In this case, the additional weight section 230 is connected to the sensor chip 210, and the projecting section 232 of the additional weight section 230 is disposed inside the first region 121 of the package 120 in such a manner that it is separated from the package 120.

As shown in FIG. 12C, the electrode pads 214 of the sensor chip 210 are connected with the connection pads 125 of the package 120 by wire bonding. As shown in FIG. 12D, a lid section 140 which hermetically seals the interior of the package 120 is formed. By means of the steps described above, the semiconductor apparatus according to the first embodiment of the present invention is formed.

### Third Embodiment

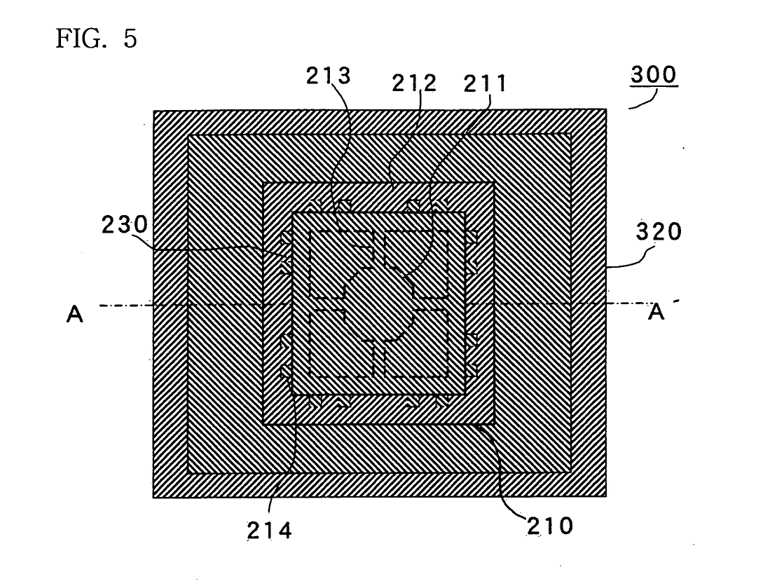

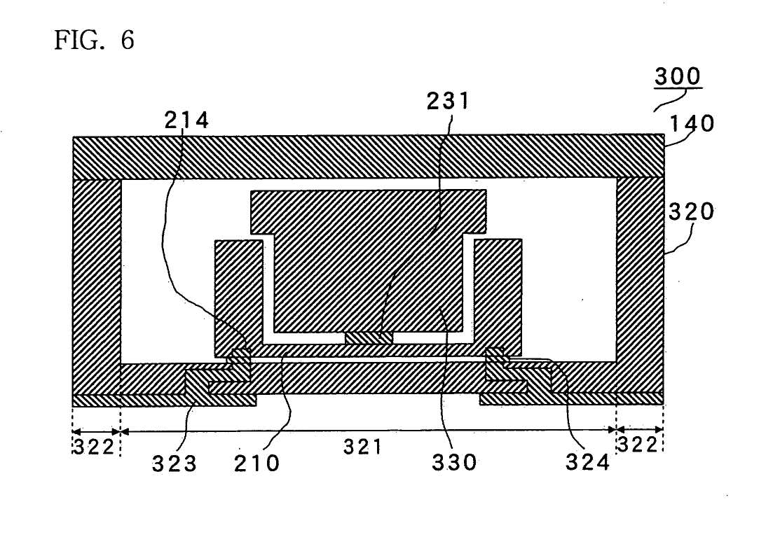

FIG. 5 is a plan view of a semiconductor apparatus according to a third embodiment of the present invention and in order to clarify the positional relationships inside the semiconductor apparatus, the lid member is omitted from the drawing. Furthermore, FIG. 6 is a cross-sectional view along A-A′ of the semiconductor apparatus shown in FIG. 5. Parts which are similar to those of the first embodiment and the second embodiment are labeled with the same reference numerals and detailed description thereof is omitted here.

The semiconductor apparatus 300 according to the third embodiment of the present invention comprises a sensor chip 210, a package 320 on which the sensor chip is mounted, an additional weight section 330 which is connected to the sensor chip 210, and a lid section 140 which covers the sensor chip 210 as well as being connected to the package 320. In FIG. 5, as stated previously, the lid section 140 is omitted from the illustration, and the outer perimeter of the sensor chip 210 and the outer perimeter of the additional weight section 330 are indicated by thick lines, while the weight section 211 and the beam sections 213 of the sensor chip 210 to the lower side of the additional weight section 330 are indicated by dotted lines. The sensor chip 210 used in the third embodiment of the present invention is similar to that of the second embodiment, and the surface on which the electrode pads 214 are provided is installed so as to oppose the mounting surface of the package 320. The package 320 comprises a first region 321 having a first thickness, in the central portion of the package 320, and a second region having a second thickness, greater than the first thickness, which surrounds the first region. The first region 321 comprises the surface on which the sensor chip 210 is mounted, as described above, and connection pads 323 are formed thereon, in the regions which correspond to the electrode pads 214 of the sensor chip 210. The connection pads 323 are connected electrically to the external electrodes of an external substrate on which the semiconductor apparatus 300 is mounted, for example, amounting substrate. Here, similarly to the first embodiment, if the package 320 is made of a ceramic material, for example, the connection pads 323 are formed by bonding together a plurality of layers, and the wires which connect the connection pads 323 and the external electrodes are formed by wires passing between the layers and wires passing through a plurality of layers. If the package 320 is formed from a silicon wafer, or the like, the wires which connect the connection pads 323 and the external electrodes are formed by through electrodes, or the like. Furthermore, the electrode pads 214 and the connection pads 323 are connected by means of conducting members 324, such as bump electrodes, for example. By adopting a connection method of this kind, it is possible further to reduce the thickness of the semiconductor apparatus 300, without needing to create connections by wire bonding. Moreover, by setting the height of the bump electrodes to 5 μm, for example, it is possible to restrict the displacement of the weight section 211 of the sensor chip 210 in the downward direction, and it is also possible to improve the resistance to impact by means of the bump electrodes.

The second region 322 is the region forming the outermost perimeter of the package 320, and is the region where a lid section is installed to cover the sensor chip 210 and the additional weight section 330 while being separated from same. The package 320 is constituted by the first region 321 and the second region 322.

The additional weight section 330 has a similar shape to that of the second embodiment of the present embodiment. A projecting section 331 of the additional weight section 330 extends over the fixed section 212 of the sensor chip 210, while being separated from the fixed section 212 of the sensor chip 210. By this means, it is possible to restrict the displacement of the additional weight section 330 in the downward direction. As described above, it is also possible to restrict displacement in the downward direction by means of bump electrodes, or to restrict such displacement by means of both of the methods described above. As regards the horizontal direction, it is possible to restrict displacement of the additional weight section 330 in the horizontal direction by adjusting the distance between the side walls of the fixed section 212 of the sensor chip 210 and the additional weight section 330 which opposes the side walls of the fixed section 212. With regard to displacement in the upward direction, it is possible to restrict the displacement of the additional weight section 330 in the upward direction by adjusting the distance with respect to the lid section 140, which is described hereinafter. In this way, by adopting a composition which restricts displacement in the respective directions in this way, it is possible to improve impact resistance.

The lid section 140 used in the third embodiment of the present invention is the same as that of the first embodiment and the second embodiment, and similarly to the first embodiment and the second embodiment, it is bonded to the second region 322 of the package 320. In this case, as described above, it is possible to restrict the amount of displacement of the additional weight section 330 in the upward direction by adjusting the distance between the lid section 140 and the additional weight section 330. It is suitable for the distance between the lid section 140 and the additional weight section 330 to be set to 3 to 5 μm, for example.

By means of the composition described above, the semiconductor apparatus according to a third embodiment of the present invention is formed. By means of the semiconductor apparatus according to the third embodiment of the present invention, it is possible to ensure similar impact resistance to the first embodiment and the second embodiment. Moreover, it is also possible to make the apparatus more compact in size, similarly to the second embodiment, as well as being able further to reduce the thickness of the semiconductor apparatus.

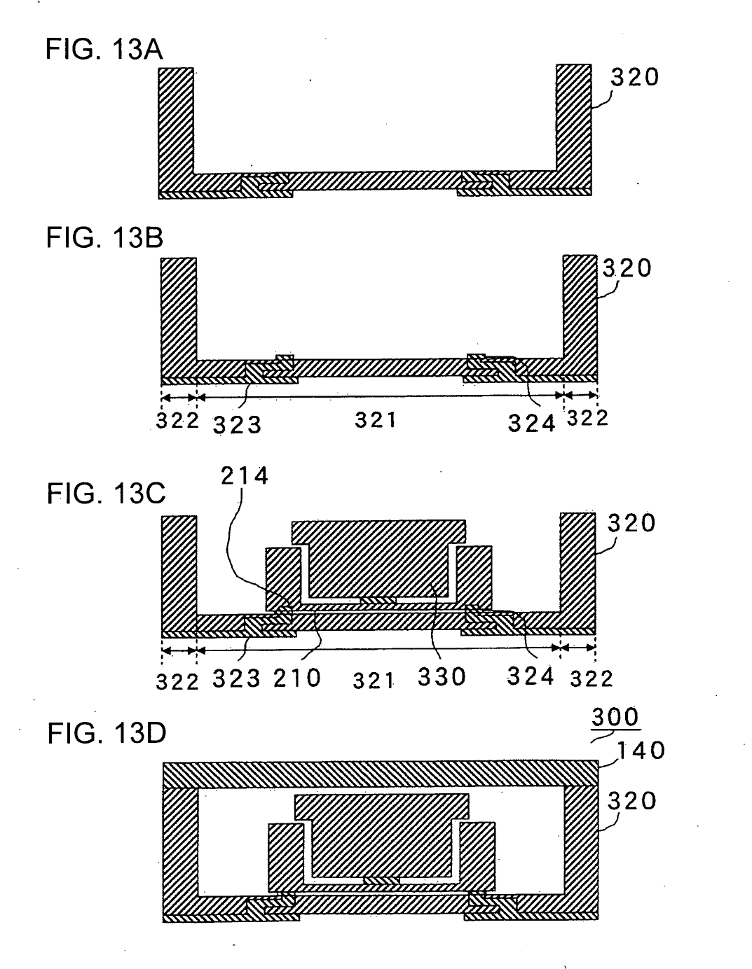

Thereupon, the method of manufacturing the semiconductor apparatus 300 according to the third embodiment of the present invention will be described with reference to FIG. 13A to FIG. 13D. As shown in FIG. 13A, a package 320 is prepared. As shown in FIG. 13B, conducting members 324 consisting of bump electrodes, for example, are formed on the first region 321 of the package 320. The conducting members 324 are formed so as to make electrical connection with connection pads 323. In this case, the conducting members 324 may be formed directly onto the connection pads 323 or they may be formed in separate positions from the connection pads 323 and connected to same via wires, or the like. In other words, the positions of the conducting members 324 may be altered appropriately in such a manner that they can connect with the electrode pads 214 of the sensor chip 210.

As shown in FIG. 13C, the electrode pads 214 of the sensor chip 210 are connected to the connection pads 323 via the conducting members 324, in the first region 321 of the package 320. In this case, it is possible to connect the sensor chip 210 to the package 320 in a state where the additional weight section 330 is connected to the sensor chip 210, and it is also possible to form the additional weight section 330 on the sensor chip 210 after installing the sensor chip 210 on the package 320.

As shown in FIG. 13D, a lid section 140 which hermetically seals the interior of the package 320 is formed. By means of the steps described above, the semiconductor apparatus 300 according to the third embodiment of the present invention is formed.

### Fourth Embodiment

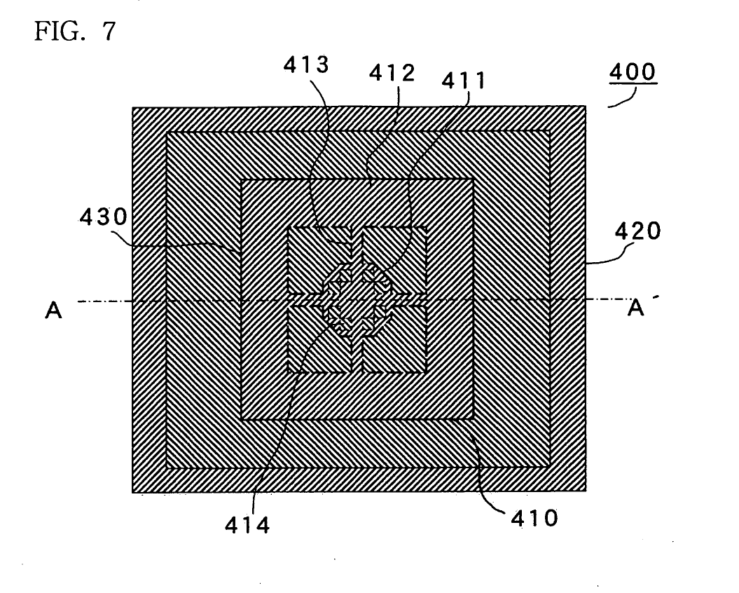

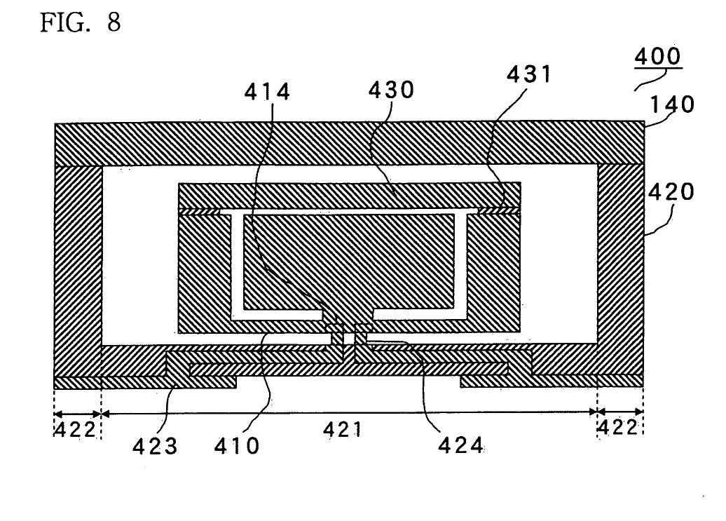

FIG. 7 is a plan view of a semiconductor apparatus 400 according to a fourth embodiment of the present invention, and the lid section is omitted from this drawing in order to clarify the positional relationships inside the semiconductor apparatus. Moreover, FIG. 8 is a cross-sectional view along A-A′ of the semiconductor apparatus 400 shown in FIG. 7. Parts which are the same as those of the first embodiment to the third embodiment are labeled with the same reference numerals and detailed description thereof is omitted here.

The semiconductor apparatus 400 according to the fourth embodiment comprises a sensor chip 410, a package 420 on which the sensor chip 110 is mounted, an additional weight section 430 connected to the sensor chip 410, and a lid section 140 which covers the sensor chip 410 and the additional weight section 430, and is also connected to the package 420. As stated above, the lid section 140 is omitted from the illustration in FIG. 7, and the outer perimeter of the additional weight section 430 is indicated by a thick line, while the sensor chip 410 on the lower side of the additional weight section 430 is indicated by a dotted line.

The sensor chip 410 used in the fourth embodiment of the present invention has the same shape as that of the first embodiment, but the positions of the electrode pads 414 are different. More specifically, when compared with the sensor chip 110 according to the first embodiment, the sensor chip 410 according to the fourth embodiment differs from the sensor chip 110 according to the first embodiment in that the electrode pads 114 are formed on the weight section 111. In this case, since the sensor chip 410 is fixed by means of the electrode pads 414 in a similar fashion to the third embodiment, the portion of the sensor chip 410 corresponding to the weight section 111 of the sensor chip 110 acts as a fixed section. Furthermore, the portion of the sensor chip 410 which corresponds to the fixed section 112 of the sensor chip 110 acts as a weight section. In order to simplify the description, the present embodiment is described by using reference numerals which relate to the corresponding shape. In other words, the sensor chip 410 is described in terms of a composition formed by a fixed section 411 on which an electrode pad 414 is formed, a weight section 412 which surrounds the fixed section 411 while being separated from the fixed section 411, and beam sections 413.

The package 420 used in the fourth embodiment of the present invention has the same shape as that of the third embodiment, but the positions of the connection pads 423 and the conducting members 424 are different. In other words, the sensor chip 410 is mounted on the first region 421 of the package 420, and a connection pad 423 and a conducting member 424 are formed in a region corresponding to the electrode pad 414 of the sensor chip 410. Consequently, since the position of the electrode pad in the sensor chip is different to the third embodiment and an electrode pad 414 is formed on the fixed section 411, then accordingly, the positions of the connection pad 423 and the conducting member 424 are changed to the central region.

The additional weight section 430 is connected to the weight section 412 of the sensor chip 410, and has a shape which covers the fixed section 411 while being separated from same. The additional weight section 430 and the weight section 412 are connected via an adhesive layer 431. Here, the distance of separation between the additional weight section 430 and the fixed section 411 is set to 3 to 5 μm, and similarly to the first embodiment to the third embodiment, this distance is set by means of the adhesive layer 431.

The lid section 140 used in the fourth embodiment of the present invention is the same as that of the first embodiment to the third embodiment, and the lid section 140 is bonded to the second region 422 of the package 420, similarly to the first to third embodiments. In this case, as stated previously, by adjusting the distance with respect to the additional weight section 430, it is possible to restrict the amount of displacement of the additional weight section 430 in the upward direction. It is appropriate for the distance between the lid section 140 and the additional weight section 430 to be set to approximately 5 μm, for example.

By means of the composition described above, the semiconductor apparatus according to the fourth embodiment of the present invention is constituted. By means of the semiconductor apparatus according to the fourth embodiment of the present invention, it is possible to ensure impact resistance, similarly to the first to third embodiments, and it is also possible to achieve further reduction of the thickness of the apparatus, similarly to the third embodiment. Moreover, the weight section 412 is formed to a greater size than in the first to third embodiments, and therefore it is possible to increase the moment of inertia, as well as increasing the mass of the weight, thereby allowing the sensitivity to be improved.

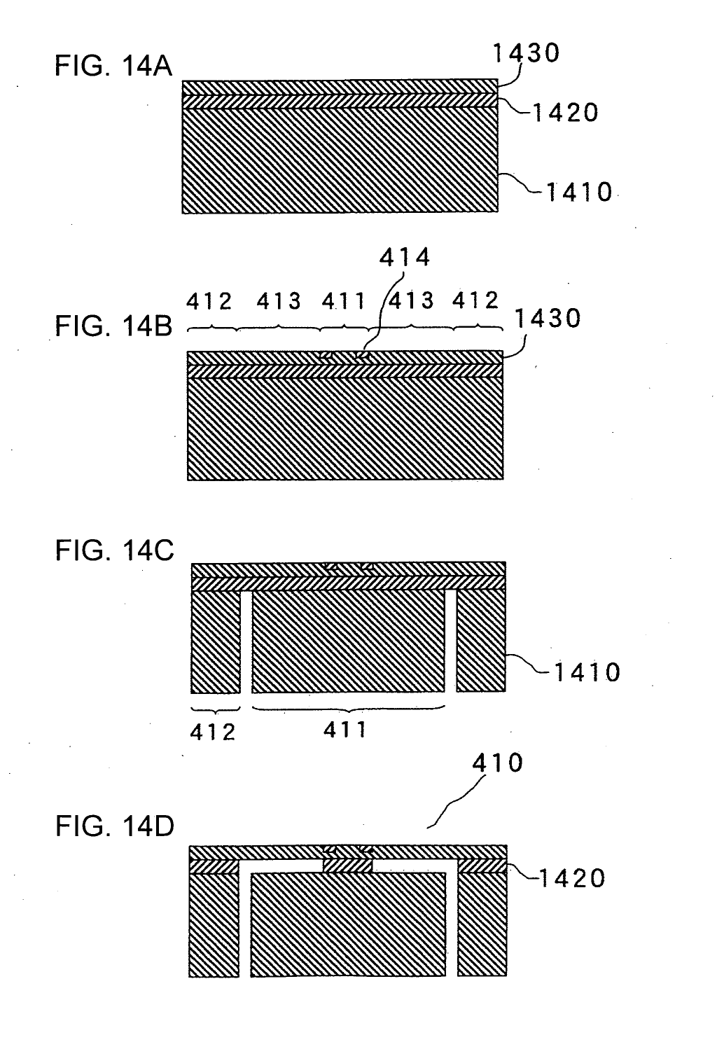

Next, the method of manufacturing the sensor chip 410 according to the fourth embodiment of the present invention is described with reference to FIG. 14A to FIG. 14D. As shown in FIG. 14A, the sensor chip 410 according to the fourth embodiment of the present invention is formed by a laminated substrate consisting of three layers, namely, a supporting substrate 1410, an insulating layer 1420 and an SOI layer 1430.

As shown in FIG. 14B, elements required for the operation of the acceleration sensor, such as electrode pads 414, piezo resistance elements (not illustrated), wires (not illustrated), and the like, are formed on the SOI layer 1430, and through holes for demarcating the fixed section 411, the weight section 412 and the beam sections 413 are formed (not illustrated).

As shown in FIG. 14C, through holes for demarcating the fixed section 411 and the weight section 412 are formed in the supporting substrate 1410, from the rear surface side. Thereupon, as shown in FIG. 14D, a portion of the insulating layer 1420 is removed, whereby the sensor chip 410 according to the fourth embodiment of the present invention is formed.

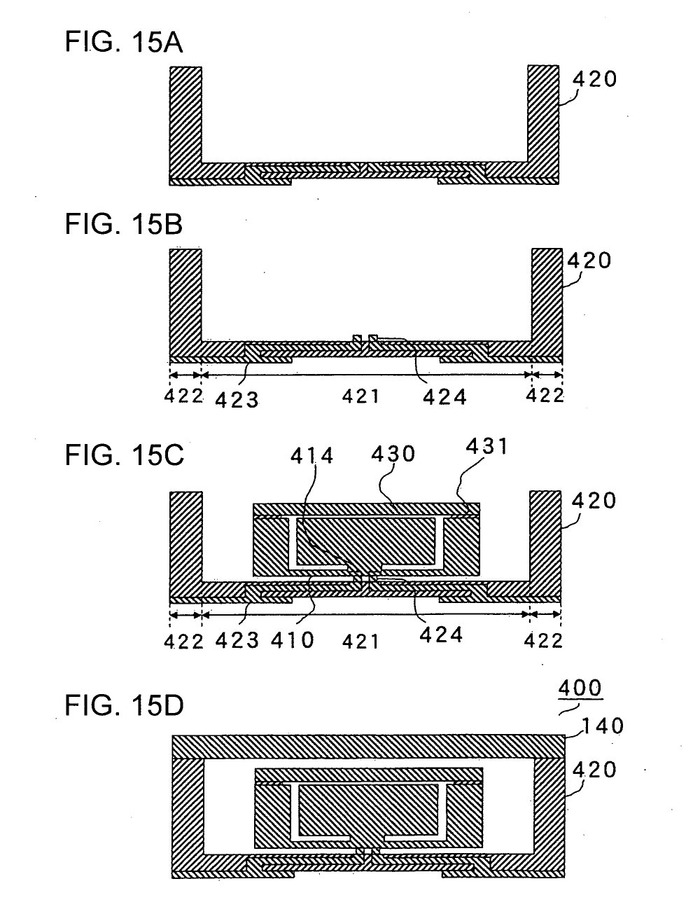

The method of manufacturing a semiconductor apparatus 400 according to the fourth embodiment of the present invention will now be described with reference to FIG. 15A to FIG. 15D. As shown in FIG. 15A, a package 420 is prepared. As shown in FIG. 15B, conducting members 424 consisting of bump electrodes, for example, are formed on the first region 421 of the package 420. The conducting members 424 are formed so as to be electrically connected with the connection pads 423. In this case, the conducting members 424 may be formed directly onto the connection pads 423, or they may be formed at positions which are distanced from the connection pads 423 and be connected to same by means of a wire, or the like. In other words, it is possible to change the position of the conducting members 424 appropriately, in such a manner that they can connect to the electrode pads 414 of the sensor chip 410.

As shown in FIG. 15C, the electrode pads 414 of the sensor chip 410 are connected via the conducting members 424 to the first region 421 of the package 420. In this case, it is possible to connect the sensor chip 410 to the package 420 in a state where the additional weight section 430 is connected to the sensor chip 410, or it is possible to form the additional weight section 430 on the sensor chip 410 after the sensor chip 410 has been mounted in the package 420.

As shown in FIG. 15D, a lid section 140 is formed to hermetically seal the interior of the package 420. By means of the steps described above, the semiconductor apparatus according to the fourth embodiment of the present invention is formed.

This application is based on Japanese Patent Application No. 2007-088547 which is herein incorporated be reference.

What is claimed is:

1. A semiconductor apparatus, comprising:
a package having a first region having a first thickness, a second region having a second thickness greater than said first thickness, said second region being surrounded by said first region, a third region having a third thickness greater than said second thickness, said third region being surrounded by said second region, and at least one connection pad electrically provided in said third region and connected to an external of said package;
a sensor chip having a first weight section, a fixed section surrounding said first weight section and being separated from said first weight section, and a beam section having an elasticity and connecting said first weight section to said fixed section, said fixed section being positioned at said second region of said package; and
a second weight section separated from both of said fixed section and said beam section and being connected to said first weight section via an adhesive layer.

2. The semiconductor apparatus according to claim 1,
wherein a junction surface between said fixed section and said second region has an extending surface extending from said second region toward said first region by a prescribed width toward and
said second weight section extends to a region existing between said extending surface of said fixed section and said first region.

3. The semiconductor apparatus according to claim 1,
wherein said first weight section has a fourth thickness, and said fixed section has a fifth thickness equal to said fourth thickness.

4. The semiconductor apparatus according to claim 2,
wherein said first weight section has a fourth thickness, and said fixed section has a fifth thickness equal to said fourth thickness.

5. The semiconductor apparatus according to claim 1,
wherein said first weight section has a fourth thickness equal to a thickness of said beam section, and said fixed section has a fifth thickness greater than said fourth thickness.

6. The semiconductor apparatus according to claim 2,
wherein said first weight section has a fourth thickness equal to said thickness of said beam section, and said fixed section has a fifth thickness greater than said fourth thickness.

7. The semiconductor apparatus according to claim 1,
further comprising a wire electrically connecting said electrode pad to said connection pad,
wherein said sensor chip has an electrode pad.

8. The semiconductor apparatus according to claim 2,
further comprising a wire electrically connecting said electrode pad to said connection pad,
wherein said sensor chip has an electrode pad.

9. The semiconductor apparatus according to claim 1,
wherein said package has a fourth region having a sixth thickness greater than said third thickness, said fourth region being surrounded by said third region, and a lid section covering said sensor chip, said lid section being disposed on said fourth region.

10. The semiconductor apparatus according to claim 2,
wherein said package has a fourth region having a sixth thickness greater than said third thickness, said fourth region being surrounded by said third region, and a lid section covering said sensor chip, said lid section being disposed on said fourth region.

11. The semiconductor apparatus according to claim 1,
wherein said package is formed from a ceramic material.

12. The semiconductor apparatus according to claim 2,
wherein said package is formed from a ceramic material.

13. The semiconductor apparatus according to claim 1,
wherein said second weight section is formed from an alloy containing copper.

14. The semiconductor apparatus according to claim 2,
wherein said second weight section is formed from an alloy containing copper.

15. A semiconductor apparatus, comprising:
a package having a first region having a first thickness, and a second region having a second thickness greater than said first thickness; said second region being surrounded by said first region; and a connection terminal electrically connected to an external of said package;
a sensor chip having a first weight section; a fixed section separated from said first weight section, surrounding said first weight section and having an electrode pad; and a beam section having an elasticity and connecting said first weight section to said fixed section; said connection terminal being connected to said electrode pad and said sensor chip being disposed on said package; and
a second weight section separated from both of said fixed section and said beam section, said second weight section being connected to said first weight section via a connection layer.

16. The semiconductor apparatus according to claim 15,
wherein said second weight section is formed so as to extend over said fixed section.

17. The semiconductor apparatus according to claim 15,
further comprising a lid section disposed on said second region of said package and covering said sensor chip and said second weight section, said lid section being separated from said sensor chip and said second weight section.

18. The semiconductor apparatus according to claim 16,
further comprising a lid section disposed on said second region of said package and covering said sensor chip and said second weight section, said lid section being separated from said sensor chip and said second weight section.

19. A semiconductor apparatus, comprising:
a package having a first region having a first thickness, a second region having a second thickness greater than said first thickness, said second region surrounded by first region, and a connection terminal provided in said first region and connected electrically to an external of said package;
a sensor chip, disposed on said package, having a fixed section having an electrode pad, a first weight section surrounding said fixed section while being separated from said fixed section, and a beam section having an elasticity and connecting said fixed section to said first weight section, said connection terminal being connected to said electrode pad; and
a second weight section formed on said first weight section and partially covering said fixed section, said second weight being separated from said fixed section.

20. The semiconductor apparatus according to claim 19, further comprising a lid section disposed on said second region of said package and partially covering said second weight section, said lid section being separated from said second weight section.
